(19) United States
(12) Patent Application Publication
(10) Pub. No.: US 2026/0092967 A1
(43) Pub. Date: Apr. 2, 2026

(54) BUILT-IN SELF-TESTING SYSTEM

(71) Applicant: Renesas Electronics Corporation, Tokyo (JP)

(72) Inventor: Andreas TWARDY, Dusseldorf (DE)

(73) Assignee: Renesas Electronics Corporation, Tokyo (JP)

(21) Appl. No.: 18/903,632

(22) Filed: Oct. 1, 2024

(51) Int. Cl. G01R 31/28

(52) U.S. Cl. CPC G01R 31/2884

(57) ABSTRACT

A built-in self-test (BIST) system for an electronic circuit is provided. The system includes test circuitry and a clock circuit. The test circuitry applies a test procedure to the electronic circuit. The clock circuit is configured to provide a clock signal to the test circuitry and to adjust a clock frequency of the clock signal.

### BACKGROUND

The present disclosure relates to a built-in self-test (BIST) system for an electronic circuit.

Built-in self-test (BIST) is a process used by a device to test itself. The BIST process is commonly applied during the start-up phase of a device to ensure that the device functions correctly during its normal operation.

BIST is commonly used in automotive applications and can ensure that the system meets compliance standards, for example relating to the Automotive Safety Integrity Level (ASIL) classification system.

For example, during the power-up/start-up phase of a microcontroller unit (MCU) implemented within an automotive system, such as may be used in an anti-lock braking system (ABS) of a car, a BIST process is forcibly executed to ensure a correct operation of the device in compliance with ASIL requirements.

### SUMMARY

It is desirable to provide an improved built-in self-testing system for use with an electronic circuit.

According to a first aspect of the disclosure there is provided a built-in self-test (BIST) system for an electronic circuit comprising test circuitry for applying a test procedure to the electronic circuit, and a clock circuit configured to provide a clock signal to the test circuitry, and adjust a clock frequency of the clock signal.

Optionally, the test circuitry is configured to apply the test procedure to the electronic circuit during a power up phase.

Optionally, the test circuitry is a digital logic circuit.

Optionally, the BIST system is configured to be couplable to a power supply.

Optionally, the power supply comprises a battery.

Optionally, the electronic circuit is configured to be couplable to the power supply.

Optionally, the BIST system and the electronic circuit are implemented in an integrated circuit.

Optionally, the integrated circuit is a microcontroller unit (MCU) or a system-on-chip (SoC).

Optionally, the BIST system is configured to be operable in a first mode or a second mode, and switch between the first mode and the second mode, wherein the clock circuit is configured to adjust the clock frequency of the clock signal to a first frequency value during the first mode, and/or adjust the clock frequency of the clock signal to a second frequency value during the second mode.

Optionally, the first mode is a high-power mode, the second mode is a low-power mode, and the first frequency value is greater than the second frequency value.

Optionally, the clock circuit is configured to provide the clock signal having an initial frequency value prior to adjusting the clock frequency of the clock signal.

Optionally, the BIST system comprises a memory element for storing the initial frequency value, wherein the clock circuit is configured to receive the initial frequency value from the memory element.

Optionally, the memory element comprises a non-volatile memory element.

Optionally, the non-volatile memory element is flash memory comprising option bytes, and the initial frequency value is stored in the option bytes.

Optionally, the clock circuit comprises a frequency adjustment unit configured to receive the clock signal from a clock signal generator, adjust the clock frequency of the clock signal received from the clock signal generator, and provide the clock signal having the adjusted clock frequency to the test circuitry.

Optionally, the frequency adjustment unit comprises a prescaler.

Optionally, the clock circuit comprises the clock signal generator.

Optionally, the electronic circuit is configured to receive the clock signal from the clock signal generator.

According to a second aspect of the disclosure there is provided an apparatus comprising an electronic circuit, and a built-in self-test (BIST) system for the electronic circuit, the BIST system comprising test circuitry for applying a test procedure to the electronic circuit, and a clock circuit configured to provide a clock signal to the test circuitry, and adjust a clock frequency of the clock signal provided to the test circuitry.

It will be appreciated that the apparatus of the second aspect may include any of the features set out in the first aspect and can incorporate other features described herein.

According to a third aspect of the disclosure there is provided a method of performing a test procedure on an electronic circuit using a built-in self-test (BIST) system comprising applying a test procedure to the electronic circuit using test circuitry, providing a clock signal to the test circuitry using a clock circuit, and adjusting a clock frequency of the clock signal provided to the test circuitry using the clock circuit.

It will be appreciated that the method of the third aspect may include providing and/or using features set out in the first and/or second aspects, and can incorporate other features as described herein.

### BRIEF DESCRIPTION OF THE DRAWINGS

The disclosure is described in further detail below by way of example and with reference to the accompanying drawings in which:

FIG. 1A is a schematic of a BIST system for an electronic circuit in accordance with a first embodiment of the present disclosure.

FIG. 1B is a timing graph showing an example of the clock signal during the first mode for an example operation of the BIST system of FIG. 1A.

FIG. 1C is a timing graph showing an example of the clock signal during the second mode for the example operation of the BIST system of FIG. 1A.

FIG. 1D is a schematic of a specific embodiment of the BIST system and the electronic circuit in accordance with a second embodiment of the present disclosure.

FIG. 1E is a schematic of a specific embodiment of the BIST system and the electronic circuit in accordance with a third embodiment of the present disclosure.

FIG. 2A is a timing graph showing a supply current as it varies with time for a known BIST system.

FIG. 2B is a timing graph showing the current consumption for a practical implementation of the BIST system and the electronic circuit.

FIG. 3A is a schematic of a specific embodiment of the BIST system for the electronic circuit, in accordance with a fourth embodiment of the present disclosure.

FIG. 3B is a schematic of a specific embodiment of the BIST system for the electronic circuit, in accordance with a fifth embodiment of the present disclosure.

FIG. 4A is a schematic of a specific embodiment of the BIST system in accordance with a sixth embodiment of the present disclosure.

FIG. 4B is a schematic of a further specific embodiment of the BIST system in accordance with a seventh embodiment of the present disclosure.

### DETAILED DESCRIPTION

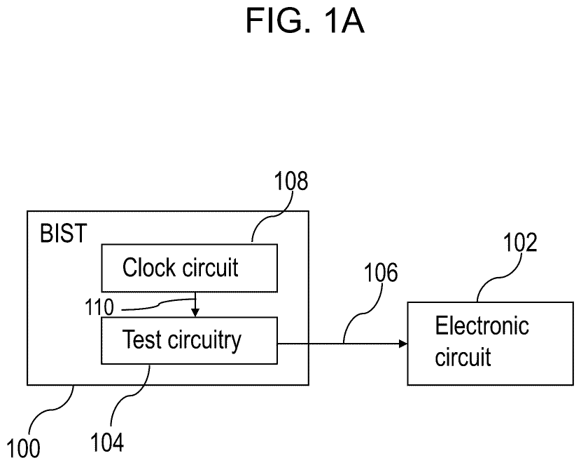

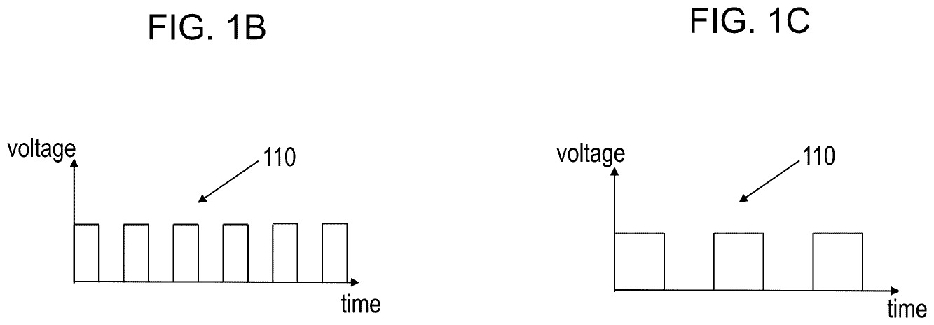

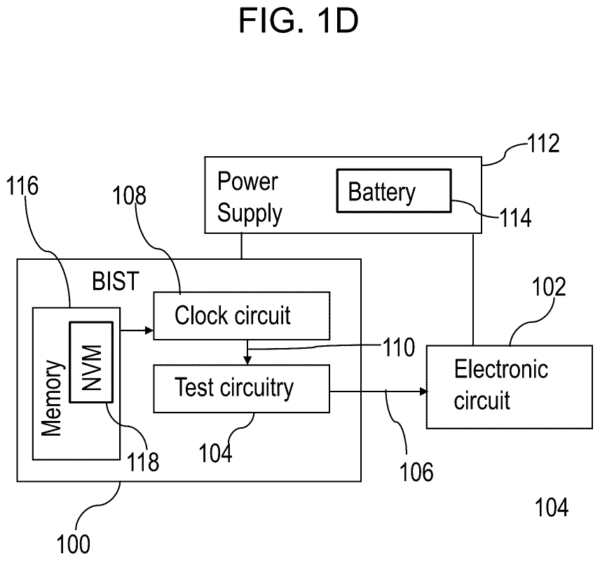

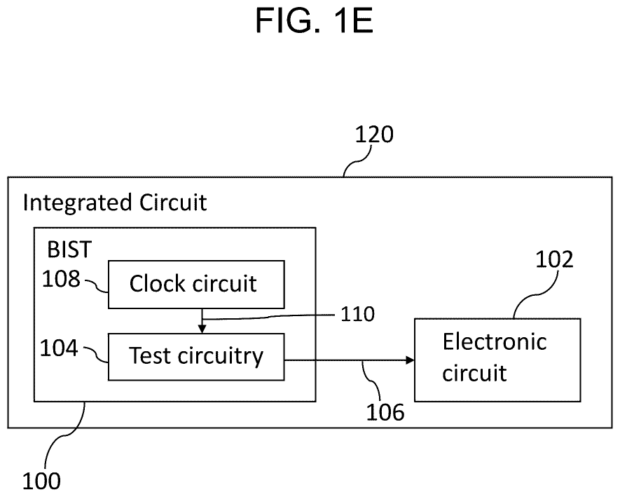

FIG. 1A is a schematic of a BIST system 100 for an electronic circuit 102 in accordance with a first embodiment of the present disclosure. The BIST system 100 comprises test circuitry 104. During operation, the test circuitry 104 applies a test procedure to the electronic circuit 102. It will be appreciated that the test procedure may be referred to as a “BIST process.” The test circuitry 104 may be a digital logic circuit.

In a specific embodiment, the test circuitry 104 may, for example, apply the test procedure by providing a control signal 106 to the electronic circuit 102, that causes the electronic circuit 102 to perform a sequence of steps to verify that it is functioning correctly.

In a specific embodiment, the control signal 106 may provide an instruction for the electronic circuit 102 to carry out the sequence of steps, with the data necessary for performing the sequence of steps being stored in a memory element (not shown). The memory element may be an internal memory element of the electronic circuit 102 or may be a memory element that is external to the electronic circuit 102. In a further embodiment, the control signal 106 may include the data relating to the sequence of steps to be performed by the electronic circuit 102.

In a specific embodiment, the electronic circuit 102 may provide an indication of the status of the test procedure, which may include information on whether the electronic circuit 102 has been assessed as functioning correctly based on its performance in the test procedure. The indication may be provided to the BIST system 100 which may respond differently based on a successful or unsuccessful test procedure.

Once the electronic circuit 102 has been assessed as functioning correctly based on the success of the test procedure, the electronic circuit 102 may progress on to a new operational phase, for example relating to the normal operation of the electronic circuit 102.

The test circuitry 104 may be configured to apply the test procedure during a power up phase. The power up phase may occur between a low-power phase, where the electronic circuit 102 is substantially inactive, and an operational phase where the electronic circuit 102 is performing its normal operation. The power up phase may be referred to as a start-up phase. The low-power phase may be a phase where minimal or no power is provided to the electronic circuit 102.

The BIST system 100 further comprises a clock circuit 108 that is configured to provide a clock signal 110 to the test circuitry 104. The clock signal 110 may oscillate between high and low states at a clock frequency, with the operation of the test circuitry 104 being synchronised to the clock frequency. The clock signal 100 may, for example, be a voltage signal having a square wave profile and a fixed duty cycle.

The clock circuit 108 is further configured to adjust the clock frequency of the clock signal 110.

Known BIST systems operate with a fixed clock frequency, which results in a BIST process having a fixed execution time and fixed current consumption. For some applications, a fixed combination of time and current is a disadvantage, and such applications may benefit from a shorter execution time or a lower current consumption during the BIST process.

In embodiments of the present disclosure, the clock frequency of the clock signal 110 is adjustable, rather than fixed. Adjustment of the clock frequency of the clock signal 110 as provided to the test circuitry 104 provides a mechanism to adjust the execution time and/or current consumption of a BIST process. It will be appreciated that the power consumption characteristics of the BIST process may be adjusted through adjustment of the current consumption.

For example, a specific application may benefit from a fast BIST process to enable the electronic circuit 102 to begin its normal operation quickly. In such an example, the clock frequency of the clock signal 110 may be increased, which will increase the current consumption (and therefore increase the power consumption) but enable a shorter BIST process execution time.

In a further example, a specific application may benefit from reduced power consumption when undertaking the BIST process. In such an example, the clock frequency of the clock signal 110 may be decreased, which will decrease the current consumption (and therefore reduce the power consumption) but require a longer BIST process execution time.

The BIST system 100 offers increased flexibility in controlling power consumption characteristics when compared with known BIST systems. The flexibility in enabling an adjustment of the current consumption characteristics of the BIST system 100 can result in reduced complexity of power circuits for the application when compared to known systems with fixed current consumption requirements.

In a specific embodiment, the BIST system 100 may be configured to be operable in a first mode or a second mode, and to switch between the two modes. During the first mode, the clock circuit 108 adjusts the clock frequency of the clock signal 110 to a first frequency value and/or during the second mode, the clock circuit 108 adjusts the clock frequency of the clock signal 110 to a second frequency value.

The clock circuit 108 may provide the clock signal 110 having an initial frequency value prior to its adjustment to the first or second frequency value.

FIG. 1B is a timing graph showing an example of the clock signal 110 during the first mode for an example operation of the BIST system 100. FIG. 1C is a timing graph showing an example of the clock signal 110 during the second mode for the example operation of the BIST system 100. In the present example, the first mode may be considered as a high-power mode, and the second mode may be considered as a low-power mode, with the first frequency value being greater than the second frequency value.

FIG. 1D is a schematic of a specific embodiment of the BIST system 100 and the electronic circuit 102 in accordance with a second embodiment of the present disclosure. In the present embodiment BIST system 100 is configured to be couplable to a power supply 112. During operation, the power supply 112 provides power to the BIST system 100. The BIST system 100 and the electronic circuit 102 may share the same power supply 112. The power supply 112 may comprise a battery 114.

In the present embodiment, the BIST system 100 comprises a memory element 116 for storing the initial frequency value. During operation the clock circuit 108 may receive the initial frequency value from the memory element 116, and then set the clock frequency of the clock signal 110 to the initial frequency value, prior to its adjustment. The first and/or second frequency values may also be stored in the memory element 116 and provided to the clock circuit 108 for adjusting the clock signal 110.

The memory element 116 may comprise a non-volatile memory (NVM) element 118. The NVM element 118 may be flash memory comprising option bytes and the initial frequency value may be stored in the option bytes.

FIG. 1E is a schematic of a specific embodiment of the BIST system 100 and the electronic circuit 102 in accordance with a third embodiment of the present disclosure. In the present embodiment, the BIST system 100 and the electronic circuit 102 are implemented in an integrated circuit 120. The BIST system 100 and the electronic circuit 102 collectively form the “device” that undergoes the BIST procedure as part of the operation of the integrated circuit 120. The integrated circuited 120 may be a microcontroller unit (MCU) or a system-on-chip (SoC).

It will be appreciated that in a further embodiment the BIST system 100 may comprise the memory element 116, for example as described in relation to FIG. 1D.

It will be appreciated that in a further embodiment, the integrated circuit 120 may be couplable to a power supply for powering one or both of the BIST system 100 and the electronic circuit 102, for example as shown for the power supply 112 of FIG. 1D.

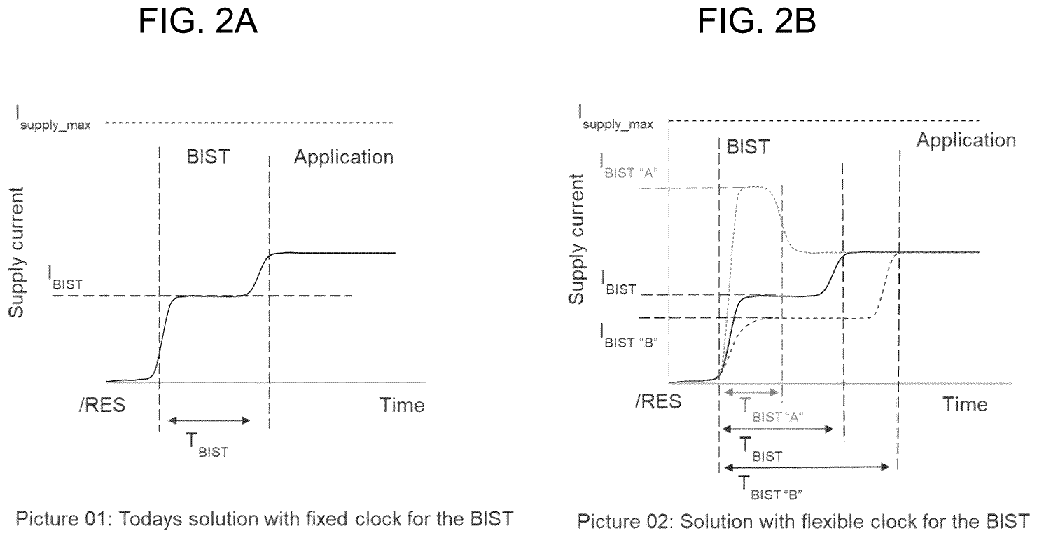

FIG. 2A is a timing graph 200 showing a supply current as it varies with time (shown by a trace 202), for a practical implementation of a known BIST system. The known BIST system uses a clock signal having a fixed clock frequency. The supply current is the current provided by a power supply to the overall device which includes the BIST system and the electronic circuit undergoing a testing procedure prior to normal operation.

Prior to a time t1, the BIST system and the electronic circuit are in a low-power state or an off state. At the time t1, the BIST system and the electronic circuit enters the start-up phase and the supply current rises to I_{BIST}, which indicates the current consumption during the BIST process. The BIST process continues for a time period T_{BIST} until a time t2, after which the supply current rises further and normal operation of the electrical circuit begins.

FIG. 2B is a timing graph 204 showing the current consumption for a practical implementation of the BIST system 100 and the electronic circuit 102. The following description will relate to the BIST system 100 and electronic circuit 102 shown in FIG. 1A, however it will be appreciated that a practical implementation of any of the embodiments described herein may exhibit the current consumption characteristics as illustrated in FIG. 2B.

A trace 206 shows the supply current as it varies with time for a high-power mode and a trace 208 shows the supply current as it varies with time for a low-power mode. The trace 202 shows the supply current as illustrated in FIG. 2A and is provided as a reference.

With reference to the high-power mode and shown by the trace 206. Prior to the time t1, the BIST system 100 and the electronic circuit 102 are in the low-power state or the off state. At the time t1, the BIST system 100 and the electronic circuit 102 enters the start-up phase and the supply current rises to I_{BIST″A″}, which indicates the current consumption during the high-power mode BIST process. The BIST process continues for a time period T_{BIST″A″} until a time t2A, after which the supply current decreases and normal operation of the electrical circuit 102 begins.

The high-power mode is suitable for applications which require a short start-up time and fast reaction time to quickly react on external signals. The increase in the frequency of the clock means that the BIST is executed faster and the test circuitry 104 can begin normal operation and therefore react quicker, when compared to the example shown in FIG. 2A.

With reference to the low-power mode and shown by the trace 208. Prior to the time t1, the BIST system 100 and the electronic circuit 102 are in the low-power state or the off state. At the time t1, the BIST system 100 and the electronic circuit 102 enters the start-up phase and the supply current rises to I_{BIST″B″}, which indicates the current consumption during the low-power mode BIST process. The BIST process continues for a time period T_{BIST″B″} until a time t2B, after which the supply current increases and normal operation of the electrical circuit 102 begins.

The low-power mode is suitable for applications which need low current consumption and is achieved by reducing the frequency of the clock which leads to lower current consumption when compared to the example shown in FIG. 2A.

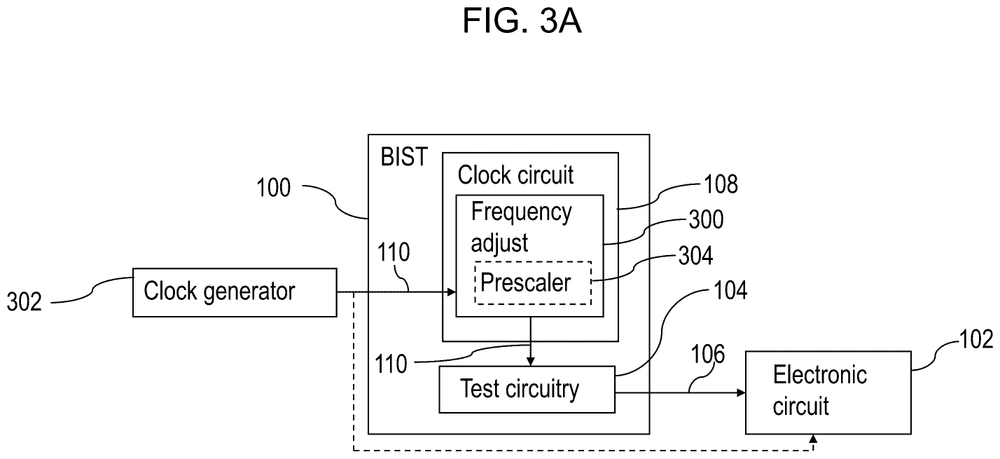

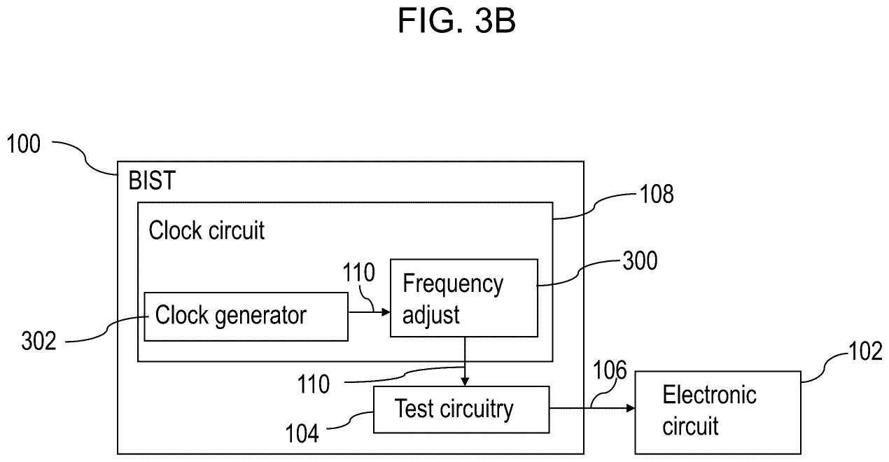

FIG. 3A is a schematic of a specific embodiment of the BIST system 100 for the electronic circuit 102, in accordance with a fourth embodiment of the present disclosure. In the present embodiment there is shown a specific implementation of the clock circuit 108. The specific implementation of the clock circuit 108 of the present embodiment may be used with any of the embodiments described herein, and in accordance with the understanding of the skilled person.

In the present embodiment, the clock circuit 108 comprises a frequency adjustment unit 300 that is configured to receive the clock signal 110 from a clock generator 302.

The frequency adjustment unit 300 then adjusts the clock frequency of the clock signal 110 and provides the clock signal 110, after adjustment, to the test circuitry 104.

The clock generator 302 may provide the unadjusted clock signal 110 to the electronic circuit 102.

The frequency adjustment unit 300 may comprise a prescaler 304 to apply the adjustment to the clock frequency of the clock signal 110, thereby controlling the power/frequency consumption characteristics of the BIST system 100. The prescaler 304 may be referred to as a frequency divider, and is a well-known circuit component that is used to reduce the frequency of a signal that it receives.

In a specific example, the prescaler 304 may reduce the clock frequency of the clock signal 110 during the high-power mode, and further reduce the clock frequency of the clock signal 110 during the low-power mode. In a further embodiment, the prescaler 304 may perform no frequency reduction operation in the high-power mode, and simply pass the clock signal 110, with a frequency reduction operation being performed by the prescaler 304 during the low-power mode.

FIG. 3B is a schematic of a specific embodiment of the BIST system 100 for the electronic circuit 102, in accordance with a fifth embodiment of the present disclosure. In the present embodiment the clock circuit 108 comprises the clock generator 302.

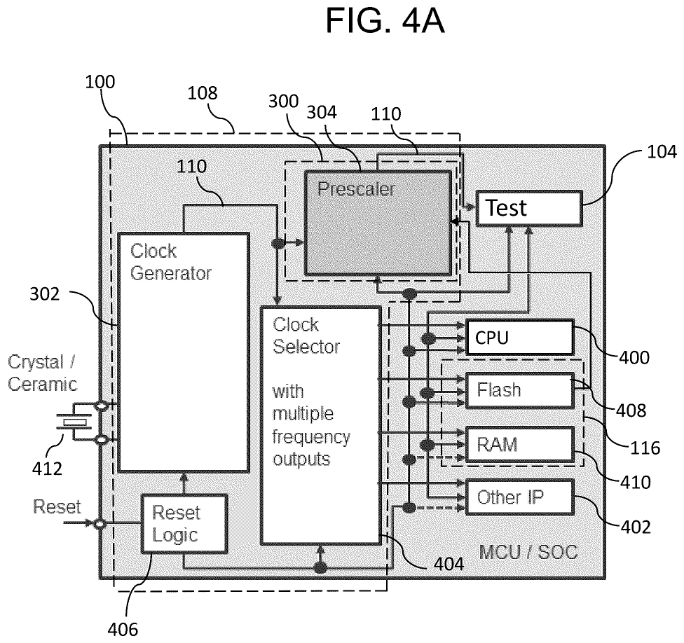

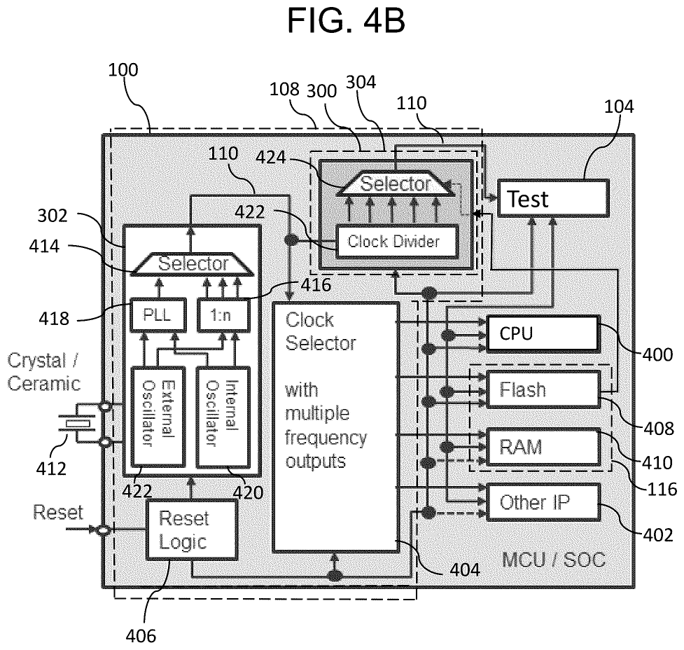

FIG. 4A is a schematic of a specific embodiment of the BIST system 100 for the electronic circuit 102 (not shown), in accordance with a sixth embodiment of the present disclosure.

In the present embodiment, the BIST system 100 further comprises a Central Processing Unit (CPU) block 400, and an “other IP” block 402; the clock circuit 108 comprises a clock selector 404 which comprises multiple frequency outputs, and reset logic 406 that is configured to receive a reset signal; the memory element 116 comprises a FLASH memory unit 408 and a RAM memory unit 410; and the clock generator 302 is coupled to a crystal oscillator 412.

During operation of the BIST system 100 of the present embodiment, there is provided an adjustable frequency which is controlled by the precaler 304 for the supply clock of the BIST, which opens the option to adjust the supply current or execution time to the needs of the application. The initial value for the frequency could be defined by option bytes stored in the Flash or NVM (“non-volatile memory”).

FIG. 4B is a schematic of a specific embodiment of the BIST system 100 for the electronic circuit 102 (not shown), in accordance with a seventh embodiment of the present disclosure. In the present example there is shown specific embodiments of the clock generator 302 and the prescaler 304.

The clock generator 302 may comprise a selector 414 for the main clock; one or more clock dividers 416 and/or one or more PLL circuits 418; and one or more internal oscillators 420 and/or one or more external oscillators 422.

The prescaler 304 may comprise a clock divider 422 that is configured to divide the main clock into fractions of the main clock. The main clock is derived from the clock generator 302. The prescaler 304 may further comprise a selector 424 configured to select the desired frequency from the clock divider 422 and provide it to the test circuitry 104. The selector 424 may be controlled by an “option byte” which was prior to “System Reset” stored in the FLASH memory unit 408.

In summary, embodiments of the present disclosure may be used in an MCU or SoC product which has a BIST process that is executed during a power-up/start-up phase. Typically, applications with ASIL standards require a BIST to be executed during power/start-up to ensure a proper operation.

Embodiments of the present disclosure may be used to control the current/power consumption characteristics of a device using a BIST process. The introduction of an adjustable frequency for the supply clock of the BIST, as provided by the embodiments described herein, allows the supply current or execution time to be adjusted to meet the needs of a specific application.

As the power requirements can be controlled, the use of an adjustable clock frequency for the BIST execution can result in a greater number of options for the design of the power supply when compared with systems using a fixed frequency clock. Specifically, the design of the power circuits is simplified when compared to known systems, and therefore there is provided a reduction in design time, testing time and cost.

Common reference numerals and variables between figures represent common features.

Various improvements and modifications may be made to the above without departing from the scope of the disclosure.

1. A built-in self-test (BIST) system for an electronic circuit, comprising:
test circuitry for applying a test procedure to the electronic circuit; and
a clock circuit configured to:
provide a clock signal to the test circuitry; and
adjust a clock frequency of the clock signal.

2. The BIST system of claim 1, wherein the test circuitry is configured to apply the test procedure to the electronic circuit during a power up phase.

3. The BIST system of claim 1, wherein the test circuitry is a digital logic circuit.

4. The BIST system of claim 1, wherein the BIST system is configured to be couplable to a power supply.

5. The BIST system of claim 4, wherein the power supply comprises a battery.

6. The BIST system of claim 4, wherein the electronic circuit is configured to be couplable to the power supply.

7. The BIST system of claim 1, wherein the BIST system and the electronic circuit are implemented in an integrated circuit.

8. The BIST system of claim 7, wherein the integrated circuit is a microcontroller unit (MCU) or a system-on-chip (SoC).

9. The BIST system of claim 1, wherein the BIST system is configured to:
be operable in a first mode or a second mode; and
switch between the first mode and the second mode;
wherein:
the clock circuit is configured to:
adjust the clock frequency of the clock signal to a first frequency value during the first mode; and/or
adjust the clock frequency of the clock signal to a second frequency value during the second mode.

10. The BIST system of claim 9, wherein:
the first mode is a high-power mode;
the second mode is a low-power mode; and
the first frequency value is greater than the second frequency value.

11. The BIST system of claim 9, wherein the clock circuit is configured to provide the clock signal having an initial frequency value prior to adjusting the clock frequency of the clock signal.

12. The BIST system of claim 11, further comprising a memory element for storing the initial frequency value, wherein the clock circuit is configured to receive the initial frequency value from the memory element.

13. The BIST system of claim 12, wherein the memory element comprises a non-volatile memory element.

14. The BIST system of claim 13, wherein:
the non-volatile memory element is flash memory comprising option bytes; and
the initial frequency value is stored in the option bytes.

15. The BIST system of claim 1, wherein the clock circuit comprises a frequency adjustment unit configured to:
receive the clock signal from a clock signal generator;
adjust the clock frequency of the clock signal received from the clock signal generator; and
provide the clock signal having the adjusted clock frequency to the test circuitry.

16. The BIST system of claim 15, wherein the frequency adjustment unit comprises a prescaler.

17. The BIST system of claim 15, wherein the clock circuit comprises the clock signal generator.

18. The BIST system of claim 15, wherein the electronic circuit is configured to receive the clock signal from the clock signal generator.

19. An apparatus comprising:
an electronic circuit; and
a built-in self-test (BIST) system for the electronic circuit, the BIST system comprising:
test circuitry for applying a test procedure to the electronic circuit; and
a clock circuit configured to:
provide a clock signal to the test circuitry; and
adjust a clock frequency of the clock signal provided to the test circuitry.

20. A method of performing a test procedure on an electronic circuit using a built-in self-test (BIST) system, the method comprising:
applying a test procedure to the electronic circuit using test circuitry;
providing a clock signal to the test circuitry using a clock circuit; and
adjusting a clock frequency of the clock signal provided to the test circuitry using the clock circuit.
